(19) United States
(12) Patent Application Publication
(10) Pub. No.: US 2005/0247976 A1
(43) Pub. Date: Nov. 10, 2005

(54) Notched spacer for CMOS transistors

(76) Inventors: Steve Ming Ting, Bridgewater, NJ (US); Chih-Hao Wang, Hsin-Chu (TW)

Correspondence Address: SLATER & MATSIL, L.L.P., 17950 PRESTON ROAD, SUITE 1000, DALLAS, TX, 75252, US

(21) Appl. No.: 10/840,125

(22) Filed: May 6, 2004

(51) Int. Cl. H01L 29/76

(52) U.S. Cl. 257/344

(57) ABSTRACT

A notched spacer for CMOS transistors and a method of manufacture is provided. A gate electrode is formed on a substrate. A first ion implant mask is formed alongside the gate electrode such that the first ion implant mask is at least partially removed along the surface of the substrate. A first ion implant is performed at an oblique angle to the surface of the substrate to implant impurities of a first conductivity type in the substrate beneath at least a portion of the gate electrode. A second ion implant is performed at an angle normal to the surface of the substrate to implant impurities of a second conductivity type to form source/drain extensions of the CMOS transistors. Additional spacers and ion implants may be performed to fabricate graded source/drain regions.

### TECHNICAL FIELD

The present invention relates generally to semiconductor devices, and more particularly, to notched spacers for complementary metal oxide-semiconductor transistors.

### BACKGROUND

Complementary metal-oxide-semiconductor (CMOS) technology is the dominant semiconductor technology used for the manufacture of ultra-large scale integrated (ULSI) circuits today. Size reduction of the semiconductor structures has provided significant improvement in the speed, performance, circuit density, and cost per unit function of semiconductor chips over the past few decades. Significant challenges, however, are faced as the sizes of CMOS devices continue to decrease.

For example, as the length of the gate electrode of a CMOS transistor is reduced, the source and drain regions increasingly interact with the channel and gain influence on the channel potential and the gate dielectric. Consequently, a transistor with a short gate length suffers from problems related to the inability of the gate electrode to substantially control the on and off states of the channel. Phenomena such as reduced gate control associated with transistors with short channel lengths are termed short-channel effects.

One method of reducing the influence of the source and drain on the channel and the gate dielectric is to introduce additional impurities in the channel region of a type opposite the source/drain implants. For example, a PMOS transistor is commonly formed on an n-type silicon substrate (or an n-well formed on a p-type substrate). Source/drain regions are formed on the substrate by implanting p-type impurities in the substrate using the gate electrode as a mask. To reduce the short channel effects, impurity regions, commonly referred to as halo implants or pocket injections, are formed by implanting additional n-type impurities in the area of the source/drain regions prior to forming the source/drain extensions. The halo implants typically implant impurities at an oblique angle to the surface of the substrate such that a high concentration of impurities is implanted below portions of the gate electrode. The source/drain extension is then formed by implanting p-type impurities, typically at an angle normal to the surface of the substrate. One or more spacers and implants are then performed to complete the source/drain regions.

In order to control the concentration and depth of halo implants, attempts have been made to form a notched structure to act as a mask. A notch or notched mask at the base of the gate electrode permits enhanced lateral penetration of the halo implants underneath the gate electrode without increasing the depth of the implant as would be required if the energy or angle of the implant were increased. Some attempts have utilized a notched gate electrode such that the gate electrode is notched or thinner along the surface of the substrate. These types of structures are generally difficult to control the length of the gate electrode and, thus, are difficult to control the electrical characteristics.

Other attempts have used thin spacers formed on the side of the gate electrode. The thin spacers are typically formed of silicon oxide covered by a thin layer of silicon nitride. The silicon nitride film is patterned by dry etching to act as a hard mask during a subsequent wet etch during which a portion of the silicon dioxide along the surface of the substrate is removed, thereby forming a notch at the base of the gate. The width of the notch is determined by the combined thickness of the silicon oxide and silicon nitride layers along the gate electrode sidewalls and determines the lateral offset of the source/drain implants. The height of the notch is determined by the thickness of the oxide layer alone. Both the width and the height of the notch affect the final profile of the halo implant. This process is inherently difficult to control due to the use of two layers to form the notched spacer, in particular the thicknesses of the oxide and nitride determine the notch width and hence the relative positions of the source/drain extension implants, halo implants, and gate electrode. Furthermore, the use of dual or multiple layers of silicon oxide and silicon nitride to create the notched spacer limits the notch height to width ratio, which for given halo implant conditions, determines the lateral penetration of the halo profile. Also, a multiple layer notched spacer results in a larger mask for the source/drain implant, resulting in poor overlap and high resistance.

Therefore, there is a need for a notched spacer to improve control for a halo implant process and a source/drain extension implant process.

### SUMMARY OF THE INVENTION

These and other problems are generally reduced, solved or circumvented, and technical advantages are generally achieved, by embodiments of the present invention, which provides a notched spacer to control a halo implant process and a source/drain extension process during fabrication of a semiconductor device.

In one embodiment of the present invention, a semiconductor device is provided having a substrate and a gate electrode formed on the substrate. A first ion-implant mask is formed alongside the gate electrode such that the first ion-implant mask is partially or completely removed along the surface of the substrate. A first ion-implant region is formed of a first impurity type in the substrate wherein the first ion-implant mask acts as a mask for an ion implant performed at an oblique angle to the surface of the substrate. A second ion implant region is formed of a second impurity type wherein the first ion-implant mask acts as a mask for an ion implant performed at an angle normal to the surface of the substrate. Thereafter, an additional ion-implant mask may be formed alongside the first ion-implant mask and additional ion implants may be performed.

In another embodiment of the present invention, a semiconductor device is provided having a notched spacer alongside a gate electrode. The notched spacer is formed alongside the gate electrode such that a portion of the notched spacer is completely or partially removed along the corner formed between the surface of the substrate and the gate electrode sidewall. A second spacer is formed alongside the notched spacer.

In yet another embodiment, a method of forming a semiconductor device is provided. A gate electrode is formed on a substrate, and a first ion-implant mask is formed alongside the gate electrode such that a portion of the first ion-implant mask is removed along the surface of the substrate. A first ion implant is then performed at an oblique angle to the surface of the substrate wherein the first ion-implant mask acts as a mask. A second ion implant may be performed at an angle normal to the surface of the substrate. Thereafter, additional masks may be formed, and additional ion implants may be performed.

In yet another embodiment, another method of forming a semiconductor device is provided. A first layer is formed over a gate electrode and a substrate. A second layer is formed over the first layer. A spacer mask is formed from the second layer and an etching process is performed to pattern the first layer such that portions of the first layer along the surface of the substrate are removed. The spacer mask is removed and a first ion implant is performed at an oblique angle to the surface of the substrate. A second ion implant is performed at an angle normal to the surface of the substrate. Thereafter, additional masks may be formed, and additional ion implants may be performed.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a-1i are cross-section views of a wafer after various process steps in accordance with one embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

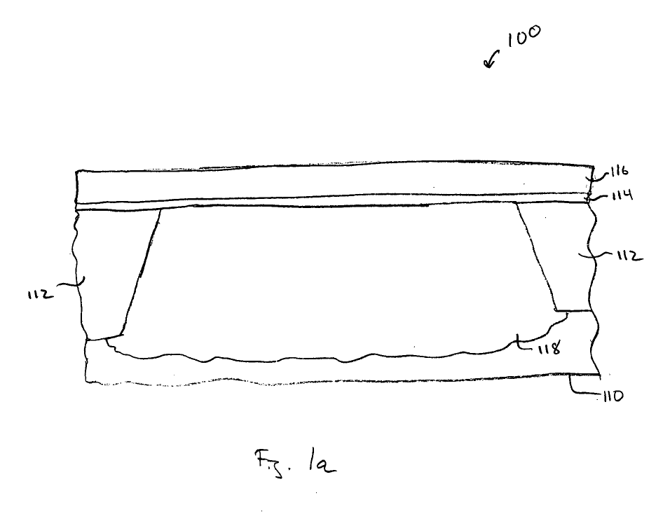

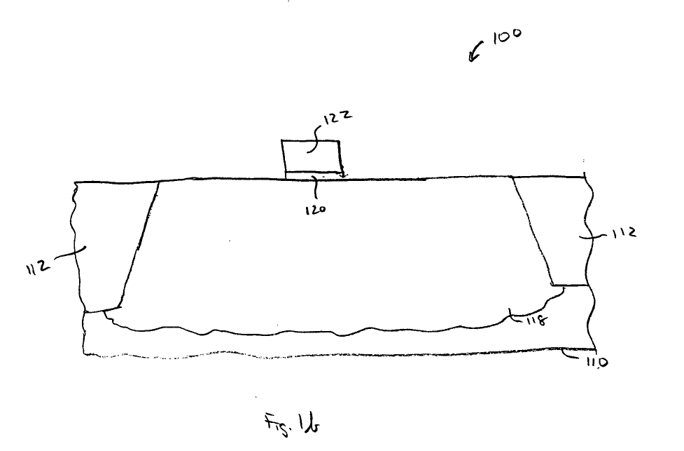

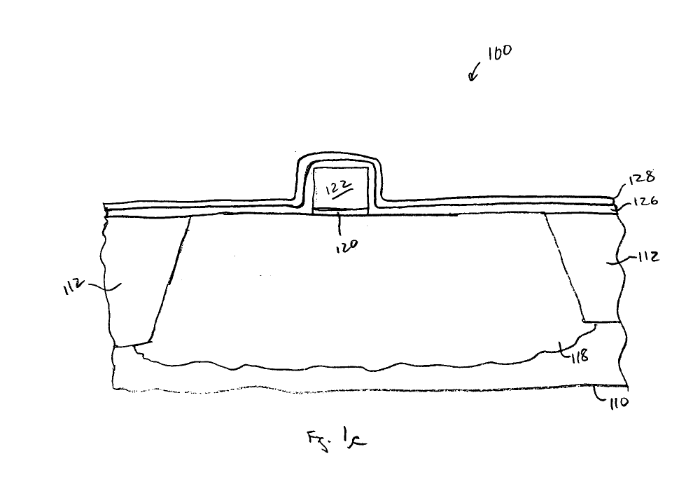

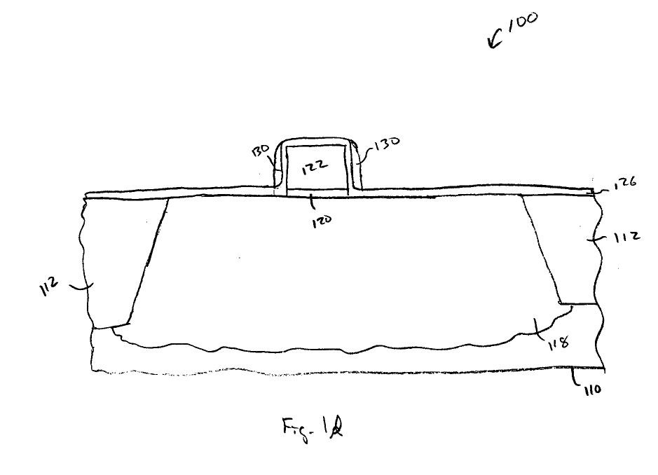

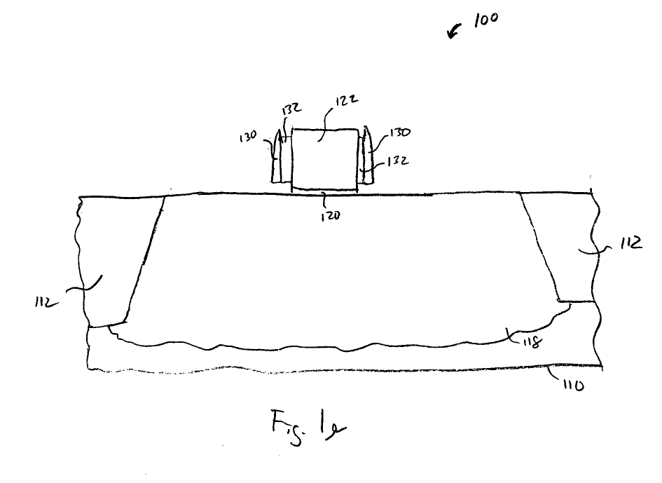

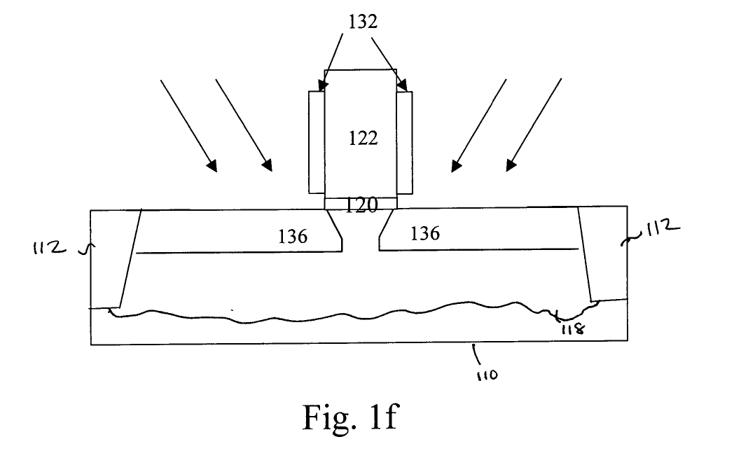

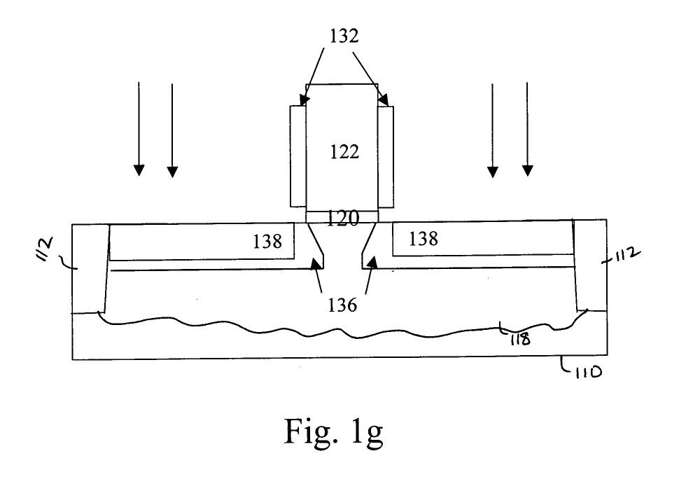

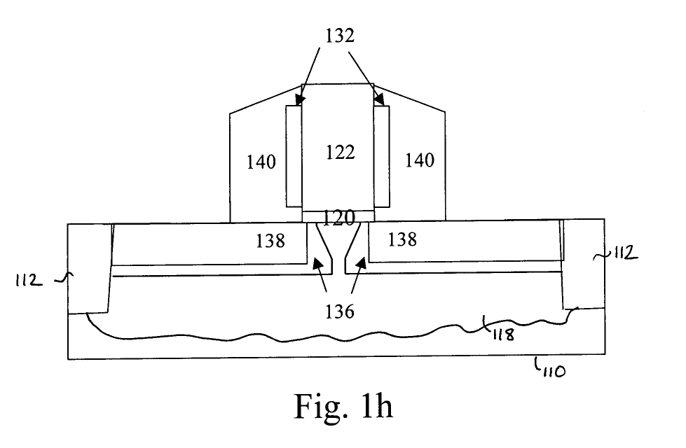

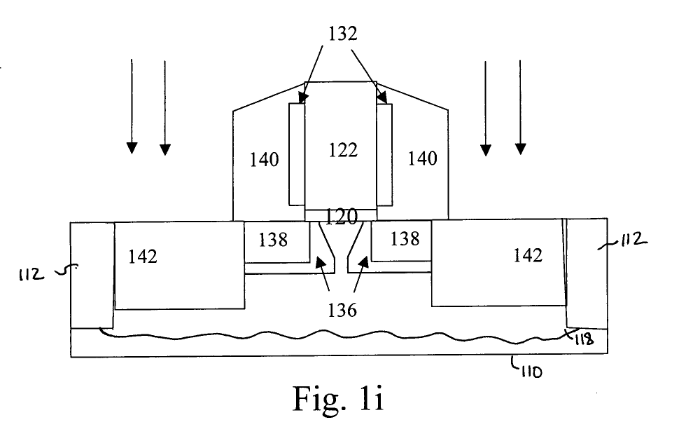

FIGS. 1a-1i illustrate one method t for fabricating a transistor having halo implants in the channel region in accordance with one embodiment of the present invention. It should be noted that the embodiment discussed herein assumes that an NMOS transistor is being fabricated on a p-type substrate. One of ordinary skill in the art will realize that the processes described herein are equally applicable to fabricating a PMOS transistor. Furthermore, the processes described herein may also be used to fabricate one or more PMOS transistors and one or more NMOS transistors on a single substrate.

Referring now to FIG. 1a, a wafer 100 is shown comprising a substrate 110 having shallow trench isolations 112, a gate dielectric layer 114, and a gate electrode layer 116 formed thereon. In the preferred embodiment, the substrate 110 comprises bulk silicon substrate having a p-well 118 formed therein. Other materials, such as germanium, silicon-germanium alloy, or the like, could alternatively be used for the substrate 110. Alternatively, the silicon substrate 110 may be an active layer of a semiconductor-on-insulator (SOI) substrate or a multi-layered structure such as a silicon-germanium layer formed on a bulk silicon layer.

The gate dielectric layer 114 comprises silicon oxide, silicon oxynitride, silicon nitride, a nitrogen-containing oxide, a high-K metal oxide, a combination thereof, or the like. A silicon dioxide gate dielectric layer 114 may be formed, for example, by an oxidation process, such as wet or dry thermal oxidation. In the preferred embodiment, the gate dielectric layer 114 is about 10 Å to about 50 Å in thickness.

The gate electrode layer 116 comprises a conductive material, such as a metal (e.g., tantalum, titanium, molybdenum, tungsten, platinum, aluminum, hafnium, ruthenium), a metal silicide (e.g., titanium silicide, cobalt silicide, nickel silicide, tantalum silicide), a metal nitride (e.g., titanium nitride, tantalum nitride), doped poly-crystalline silicon, other conductive materials, or a combination thereof. In one example, amorphous silicon is deposited and re-crystallized to create poly-crystalline silicon (poly-silicon). In the preferred embodiment in which the gate electrode is poly-silicon, the gate electrode 116 may be formed by depositing doped or undoped poly-silicon by low-pressure chemical vapor deposition (LPCVD) to a thickness in the range of about 200 Å to about 2000 Å, but more preferably about 1000 Å.

FIG. 1b illustrates the wafer 100 of FIG. 1a after the gate dielectric layer 114 and the gate electrode layer 116 of FIG. 1a have been patterned to form a gate dielectric 120 and gate electrode 122, respectively. The gate dielectric 120 and the gate electrode 122 may be patterned by photolithography techniques as is known in the art. Generally, photolithography involves depositing a photoresist material, which is then masked, exposed, and developed. After the photoresist mask is patterned, an anisotropic etching process may be performed to remove unwanted portions of the gate dielectric layer 114 (FIG. 1a) and the gate electrode layer 116 (FIG. 1a) to form the gate dielectric 120 and the gate electrode 122 as illustrated in FIG. 1b.

FIG. 1c illustrates the wafer 100 of FIG. 1b after a first dielectric layer 126 and second dielectric layer 128 have been formed. The first dielectric layer 126 preferably comprises silicon dioxide formed by LPCVD techniques using TEOS and oxygen as a precursor. Other materials, such as, for example, silicon oxynitride, silicon, a combination thereof, or the like, may also be used. In the preferred embodiment, the first dielectric layer 126 is about 10 Å to about 150 Å in thickness, but more preferably about 100 Å in thickness. It should be noted, however, that the thickness of the first dielectric layer 126 defines the width of the notched spacer as well as the minimum notch height.

The second dielectric layer 128 preferably comprises silicon nitride (Si₃N₄) that has been formed using CVD techniques using silane and ammonia as precursor gases. Other materials, such as a nitrogen containing layer other than Si₃N₄, such as SiₓN_{y}, silicon oxynitride SiOₓN_{y}, or a combination thereof, may also be used. In the preferred embodiment, the second dielectric layer 128 is about 50 Å to about 200 Å in thickness.

In FIG. 1d, the second dielectric layer 128 (FIG. 1c) is patterned to form a notched spacer masks 130 utilized in the formation of the notched-spacer. In the preferred embodiment in which the second dielectric layer 128 is Si₃N₄, the second dielectric layer 128 may be patterned by performing an anisotropic dry etch process. It should be noted that the materials for the second dielectric layer 128 and the first dielectric layer 126 are selected such that a high etch selectivity exists between the two materials. In this manner, one layer is relatively unaffected while etching or removing the other layer.

FIG. 1e illustrates the wafer 100 of FIG. 1d after the first dielectric layer 126 (FIG. 1d) has been patterned to form notched spacers 132. The first dielectric layer 126 may be patterned, for example, by performing a timed isotropic wet etch process using a solution of dilute hydrofluoric acid. The height of the notch will depend on the thickness of the first dielectric layer, the etch rate of the first dielectric layer, and etch duration.

As illustrated in FIG. 1e, the portion of the first dielectric layer 126 (FIG. 1d) located under the notched-spacer masks 130 is removed due to the isotropic etch process, thereby creating a notched spacer. The width of the notch will be dependent upon the thickness of the first dielectric layer 126 and the notch height may be controlled by varying the etch duration. Furthermore, FIG. 1e illustrates the situation in which the first dielectric layer 126 is removed completely to the gate electrode 122. In other situations, a portion of the first dielectric layer 126 may remain on the side of the gate electrode 122. This may be desirable, for example, when it is preferred to control the depth and angle of the implant or to protect the gate electrode 122 or gate dielectric 120 from damage during the etching process or other processes.

It should be further noted that if the gate dielectric 120 and the notched spacers 132 are both formed of silicon dioxide, then the etching process to form the notched spacers 132 may remove a portion of the gate dielectric 120, altering the electrical characteristics thereof. Accordingly, it may be desirable to form the gate dielectric 120 and the notched spacers 132 of different materials or to use an etching process that exhibits a high etch selectivity between the gate dielectric 120 and the notched spacers 132. For example, the gate dielectric 120 may be formed of a high-K dielectric and the notched spacers 132 may be formed of LPCVD silicon oxide. In this situation, the etching process to form the notched spacers 132 will have a high etch selectivity ratio between the gate dielectric 120 and the notched spacers 132. Alternatively, an annealing process may be performed after the etching process to repair any damage to the gate dielectric 120.

FIG. 1f illustrates the wafer 100 of FIG. 1e after the notched-spacer masks 130 (FIG. 1e) have been removed and implant regions 136 have been formed. Silicon nitride notched-spacer masks 130 may be removed, for example, by an isotropic etch process using a solution of phosphoric acid (H₃PO₄) without etching the silicon oxide of the notched spacer. As one skilled in the art will appreciate, by removing the notched-spacer masks 130 prior to forming the implant regions 136 the width of the notch is determined solely on the width of the notched spacers 132, which is more controllable than a plurality of layers as in the prior art.

In the embodiment in which an NMOS transistor is being formed, the implant regions 136 are formed by implanting p-type impurities at an oblique angle to the surface of the substrate as illustrated in FIG. 1f. For example, boron difluoride ions at a dose of about 1e13 to about 5e14 atoms/cm² and at an energy of about 5 to about 50 keV may be implanted to form the implant regions 136. Alternatively, the implanting process may use boron, indium, or the like. To form a PMOS device, the implant process may use an n-type dopant such as phosphorous, arsenic, antimony, or the like.

One skilled in the art will appreciate that the depth and the lateral dimensions of the implant regions 136 may be controlled by the angle, the dose, and the energy level of the implant. Thus, the dimensions and the density of the implant regions 136 may be customized for a particular application and for a particular gate length.

FIG. 1g illustrates the wafer 100 of FIG. 1f after the source/drain extensions 138 have been formed. In the embodiment in which an NMOS transistor is being formed, the source/drain extensions 138 are preferably formed by implanting n-type impurities at an angle normal to the surface of the substrate 110 as illustrated in FIG. 1g. For example, arsenic ions at a dose of about 5e14 to about 3e15 atoms/cm² and at an energy of about 1 to about 5 keV may be implanted to form the source/drain extensions 138. Alternatively, the implanting process may use phosphourous, antimony, or the like. To form a PMOS device, the implant process may use a p-type dopant such as boron, boron difluoride, indium, or the like.

It should be noted that the gate electrode 122 and the notched spacers 132 act as a mask for the ion implant process to form the source/drain extensions 138. Because the implant regions 136 are created by implanting at an oblique angle to the surface of the substrate 110 and the source/drain extension 138 is created by implanting at an angle normal to the surface of the substrate 110, a portion of the implant regions 136 extends beyond the source/drain extension 138 into the region directly beneath the gate electrode as illustrated in FIG. 1g, thereby creating the halo implant or pocket implant regions.

FIG. 1h illustrates wafer 100 of FIG. 1g after main spacers 140 have been formed. The main spacers 140, which form a spacer for a third ion implant, preferably comprise dielectric materials such as an oxide, silicon nitride (Si₃N₄), or a nitrogen containing layer other than Si₃N₄, such as SiₓN_{y}, silicon oxynitride SiOₓN_{y}, a combination thereof, or the like. In a preferred embodiment, the spacers 140 are formed from two dielectric layers comprising a silicon dioxide layer and an overlying silicon nitride layer deposited by LPCVD techniques. The silicon nitride layer is deposited to a thickness about 200 Å to about 1000 Å in thickness and may be patterned by performing an anisotropic etch process. The underlying silicon dioxide layer is deposited to a thickness of 20 Å to about 300 Å in thickness, and may be etched anisotropically or isotropically after the silicon nitride is patterned. Rapid thermal annealing (RTA) is typically required after implantation before any additional processing at high temperatures. Thus after implantation of the halo and source/drain extensions, typically an RTA is performed prior to formation of main spacers 140 in order to remove ion implant damage, thereby reducing dopant diffusion during the thermal cycle associated with spacer formation. Nevertheless, the implanted halo and S/D profiles inevitably undergo some diffusion deeper vertically into the p-well 118 and laterally underneath the gate dielectric 120.

FIG. 1i illustrates the wafer 100 of FIG. 1h after a third ion implant has been performed to form source/drain regions 142. The source/drain regions 142 may be formed, for example, using an n-type dopant, such as, for example, phosphorous ions at a dose of about 1e13 to about 5e15 atoms/cm³ and at an energy of about 5 to about 50 keV. Alternatively, other n-type dopants, such as arsenic, antimony, or the like, may be used. P-type dopants, such as boron, boron difluoride, indium, and the like, may be used to fabricate PMOS devices. An additional RTA is typically required after the source/drain implants to remove damage and activate the implanted dopants to ensure highly conductive source/drains and source/drain extensions. In addition to RTA, other anneals, such as flash lamp or laser anneals may also be used to remove ion implant damage and activate the dopants.

Thereafter, standard processing techniques may be used to complete fabrication of the semiconductor device. For example, the source/drain regions and the gate electrode may be silicided, inter-layer dielectrics may be formed, contacts and vias may be formed, metal lines may be fabricated, and the like.

Although the present invention and its advantages have been described in detail, it should be understood that various changes, substitutions and alterations can be made herein without departing from the spirit and scope of the invention as defined by the appended claims. For example, a PMOS transistor may be fabricated and various other materials, thicknesses, concentrations, and the like may be used. As another example, it will be readily understood by those skilled in the art that the devices and methods disclosed herein may be incorporated into semiconductor devices comprising other devices while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor device comprising:
a substrate having a well of a first conductivity type formed thereon;
a gate electrode formed on the substrate
a notched spacer formed of a first material alongside the gate electrode, the notched spacer having a notch formed along the surface of the substrate;
a first impurity region of the first conductivity type formed in the substrate at a first ion implant angle from the surface of the substrate, wherein only the notched spacer and the gate electrode act as a mask;
a second impurity region of a second conductivity type formed in the substrate at a second ion implant angle from the surface of the substrate, wherein the notched spacer and the gate electrode act as a mask;
a second spacer formed alongside the notched spacer; and
one or more additional impurity regions of the second conductivity type formed in a source/drain region in the substrate.

2. The semiconductor device of claim 1, wherein the notched spacer is formed of silicon dioxide.

3. The semiconductor device of claim 1, wherein the notched spacer is formed of silicon nitride.

4. The semiconductor device of claim 1, wherein the second spacer is formed of a material selected from the group consisting essentially of silicon dioxide and silicon nitride.

5. The semiconductor device of claim 1, wherein the notched spacer is completely removed along the surface of the substrate.

6. The semiconductor device of claim 1, wherein the first ion implant angle is oblique to the surface of the substrate.

7. The semiconductor device of claim 1, wherein the second ion implant angle is normal to the surface of the substrate.

8. The semiconductor device of claim 1, wherein the first impurity region extends beneath at least a portion of the gate electrode.

9. The semiconductor device of claim 1, wherein the first impurity region extends further laterally under the gate electrode than the second impurity region.

10. A semiconductor device comprising:
a substrate having a gate electrode formed thereon;
a notched spacer formed alongside the gate electrode such that the notched spacer does not contact the substrate, the notched spacer being a single homogeneous spacer; and
a second spacer formed alongside the notched spacer.

11. The semiconductor device of claim 10, wherein the notched spacer is formed of silicon dioxide.

12. The semiconductor device of claim 10, wherein the notched spacer is formed of silicon nitride.

13. The semiconductor device of claim 10, wherein the second spacer is formed of a material selected from the group consisting essentially of silicon dioxide and silicon nitride.

14. The semiconductor device of claim 10, further comprising a first ion implant region extending beneath at least a portion of the gate electrode.

15. The semiconductor device of claim 10, further comprising a first ion implant region and a second ion implant region, the second ion implant region being formed by an ion implant at an angle normal to the surface of the substrate wherein the second spacer acts as a mask, and the first ion implant region extending further laterally under the gate electrode than the second impurity region.

16. A method of forming a semiconductor device, the method comprising:
forming a gate electrode on a substrate, the substrate having a first conductivity type;
forming a notched spacer alongside the gate electrode such that the notched spacer is thinner along the surface of the substrate, the notched spacer comprising a single homogenous layer;
performing a first ion implant wherein only the gate electrode and the notched spacer act as masks during the first ion implant, the first ion implant using ions of the first conductivity type; and
performing one or more second ion implants using ions of a second conductivity type.

17. The method of claim 16, wherein the step of forming a notched spacer comprises forming a first layer and a second layer, forming a mask out of the second layer on the first layer such that the first layer alongside the gate electrode is covered by the mask, etching the first layer such that the first layer along the surface of the substrate next to the gate electrode is removed, removing the mask.

18. The method of claim 17, wherein the mask is formed of silicon nitride.

19. The method of claim 17, wherein the mask is formed of silicon oxide.

20. The method of claim 16, wherein the step of performing a first ion implant is performed by implanting ions at an oblique angle to the substrate such that impurities of the first conductivity type are implanted in the substrate below the gate electrode.

21. The method of claim 16, wherein the step of performing one or more second ion implants are performed at an angle normal to the surface of the substrate.

22. The method of claim 16, wherein the notched spacer is formed of silicon dioxide.

23. The method of claim 16, wherein the notched spacer is formed of silicon nitride.

24. A method of forming a semiconductor device, the method comprising:
forming a gate electrode on a substrate, the substrate having a first conductivity type;
forming a first layer over the substrate and the gate electrode;
forming a second layer over the first layer;
removing a portion of the second layer such that a spacer mask is formed on the first layer on the side of the gate electrode;
etching the first layer to form a notched spacer wherein the spacer mask acts as a mask, the etching process removing at least a portion of the second layer along the surface of the substrate;
removing the spacer mask;
performing a first ion implant after the spacer mask has been removed, the first ion implant using ions of the first conductivity type; and
performing one or more second ion implants using ions of a second conductivity type.

25. The method of claim 24, wherein the step of performing a first ion implant is performed by implanting ions at an oblique angle to the substrate such that impurities of the first conductivity type are implanted in the substrate below the gate electrode.

26. The method of claim 24, wherein the step of performing one or more second ion implants are performed at an angle normal to the surface of the substrate.

27. The method of claim 24, wherein the first layer is formed of silicon dioxide.

28. The method of claim 24, wherein the second layer is formed of silicon nitride.
